(19) United States
(12) Patent Application Publication
(10) Pub. No.: US 2015/0016877 A1
(43) Pub. Date: Jan. 15, 2015

(54) EJECTOR ASSEMBLY

(71) Applicants: Qingqing He, Beijing (CN); Jin Jin, Beijing (CN)

(72) Inventors: Qingqing He, Beijing (CN); Jin Jin, Beijing (CN)

(73) Assignee: Telefonaktiebolaget L M Ericsson (publ), Stockholm (SE)

(21) Appl. No.: 14/382,275

(22) PCT Filed: Apr. 25, 2012
(86) PCT No.: PCT/CN2012/074649

§ 371 Date: Aug. 29, 2014

(51) Int. Cl. H05K 5/02

(52) U.S. Cl. CPC H05K 5/0221
USPC 403/322.4

(57) ABSTRACT

A ejector assembly, comprising: an ejector (10) with a shape of “L”, being provided to rotate around an axis; a lock element (20), being provided to move along a direction substantially perpendicular to a plan of the rotation of the ejector (10); wherein the ejector (10) includes a cut-out portion (12), the lock element (12) includes an end portion (21), and the end portion (21) is provided to match with the cut-out portion (12) to prevent the ejector (10) from rotating.

### FIELD OF THE INVENTION

The present invention relates to an ejector assembly for a mounting attachment of an electrical apparatus.

### BACKGROUND TO THE INVENTION

Ejectors are widely used on modules to facilitate mounting and ejecting process in modularized telecommunication system. To fasten module to sub-rack/chassis, normally screws are used in company with ejectors. To disassemble modules, screws need to be unfastened before pulling ejectors. However, a misoperation occurs as screws could not be unfastened or not fully unfastened, then the ejector would be stroked to allow the misoperation.

In some solutions, for avoiding such misoperation, protectors are added on a front panel, unless screw is unfastened, the protectors would stop the ejectors from moving forward and pulling modules out. However the protectors are provided, due to design defects of the protectors, the misoperation may also occur. When the misoperation is performed, components, e.g. the ejector, the screws, and corresponding fixture, or even sub-rack, would be broken.

### SUMMARY OF THE INVENTION

According to an aspect of the present invention, an ejector assembly comprises: an ejector with a shape of “L”, being provided to rotate around an axis; a lock element, being provided to move along a direction substantially perpendicular to a plan of the rotation of the ejector; wherein the ejector includes a cut-out portion, the lock element includes an end portion, and the end portion is provided to match with the cut-out portion to prevent the ejector from rotating.

Alternatively or additionally, the ejector assembly is provided to assemble with a plate element; and a matching portion is provided on the plate element, and the lock element is provided to match with the matching portion so that the lock element is mounted on the plate element.

Alternatively or additionally, a hole portion is provided on the lock element, and the hole portion is configured that the lock element is fixed not to move by a screw going through the hole portion.

Alternatively or additionally, an axis hole is provided on the ejector, and the axis hole is configured that the ejector is mounted on the plate element by a shaft going through the axis hole.

Alternatively or additionally, further comprising a first spring, wherein the first spring is provided between the lock element and the plate element, and the first spring is configured to provide a force on the lock element along a direction substantially perpendicular to the plan of the rotation of the ejector.

Alternatively or additionally, further comprising a second spring, the second spring is provided between the ejector and the plate element, and the second spring is configured to provide a force on the ejector along a direction of the ejector rotation.

Alternatively or additionally, a positioning portion is provided on the ejector, and a positioning mated portion is provided on the plate element, and the positioning portion and the positioning mated portion are configured that the positioning portion is matched with the positioning mated portion during the ejector is mounting on the plate element.

Alternatively or additionally, when the lock element is fixed by the screw, the ejector is embedded in the plate element.

Alternatively or additionally, when the screw is free, the ejector ejects from the plate element by the force.

Alternatively or additionally, an electronic module is equipped with the ejector assembly of the present invention.

Alternatively or additionally, an electrical apparatus includes one or more electronic modules, wherein said one or more electronic modules are equipped with the ejector assembly of the present invention.

An appreciation of the objectives of the present invention and a more complete understanding of its structure may be had by studying the following description of the preferred embodiment and by referring to the accompanying drawings.

### BRIEF DESCRIPTION OF THE DRAWINGS

An embodiment of the present invention will now be described with reference to the accompanying drawings in which:

FIG. 1 is a view of the ejector assembly according to an embodiment of the present invention, and shows respective elements of the ejector assembly with being unassembled;

FIG. 2 is a view of the ejector assembly according to an embodiment of the present invention, and shows the ejector assembly with being assembled;

FIG. 3 is a view of the ejector assembly according to an embodiment of the present invention, and shows the ejector assembly with being assembled;

FIG. 4 is a view of an electronic module equipped with the ejector assembly of the present invention;

FIG. 5 is a view of an electrical apparatus including one or more electronic modules, wherein said one or more electronic modules are equipped with the ejector assembly of the present invention.

### DETAILED DESCRIPTION OF THE DRAWINGS

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the invention is to cover all modifications, equivalents and alternatives falling within the spirit and scope of the present invention as defined by the appended claims.

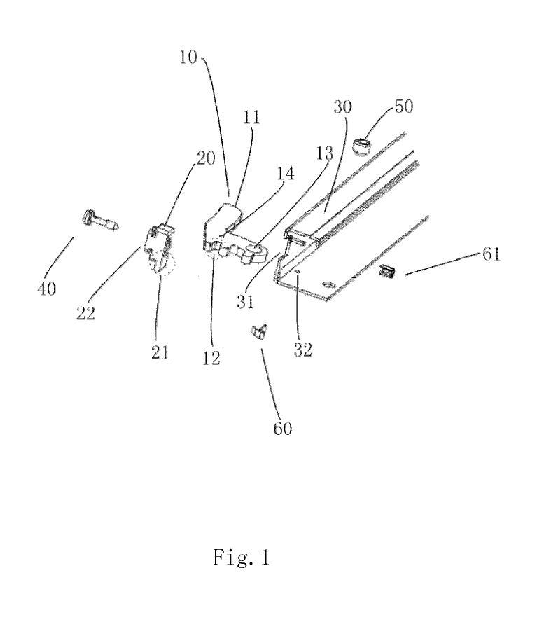

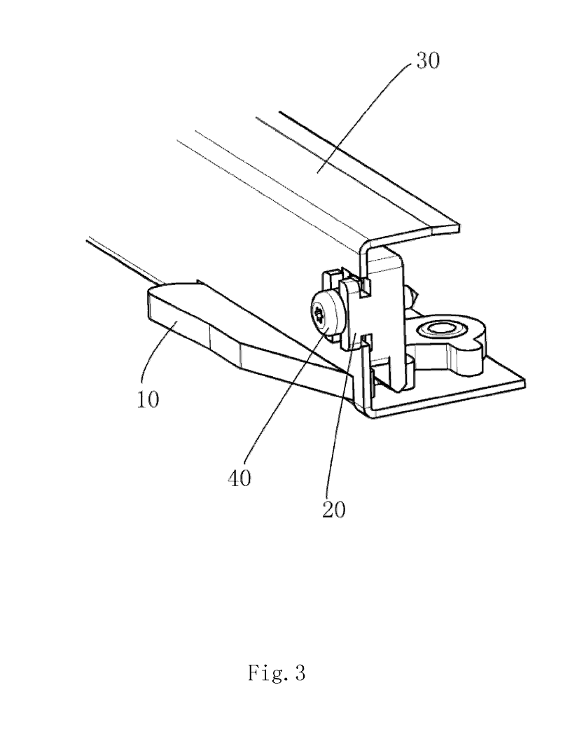

Referring to FIG. 1, the ejector assembly according to the present invention, comprises an ejector 10 with a shape of “L” , being provided to rotate around an axis; a lock element 20, being provided to move along a direction substantially perpendicular to a plan of the rotation of the ejector 10; wherein the ejector 10 includes a cut-out portion 12 (e.g. a groove), the lock element 12 includes an end portion 21, and the end portion 21 is provided to match with the cut-out portion 12 to prevent the ejector 10 from rotating. As shown in FIG. 3, the end portion of the lock element 20 is inserted into the cut-out portion of the ejector 10 so that the ejector 10 could not be rotated.

It should be noted that the shape of L does not mean the accurate L, for example, it may include a shape of arc. A person skilled in the art may provide various amendments, all of which could be deemed to be covered by the shape of L.

Referring to FIG. 1, in a preferred embodiment of the present invention, the ejector assembly is provided to assemble with a plate element 30 (e.g. a front panel); and a matching portion 31 is provided on the plate element 30, and the lock element 20 is provided to match with the matching portion 31 so as to mount the lock element 20 on the plate element 30.

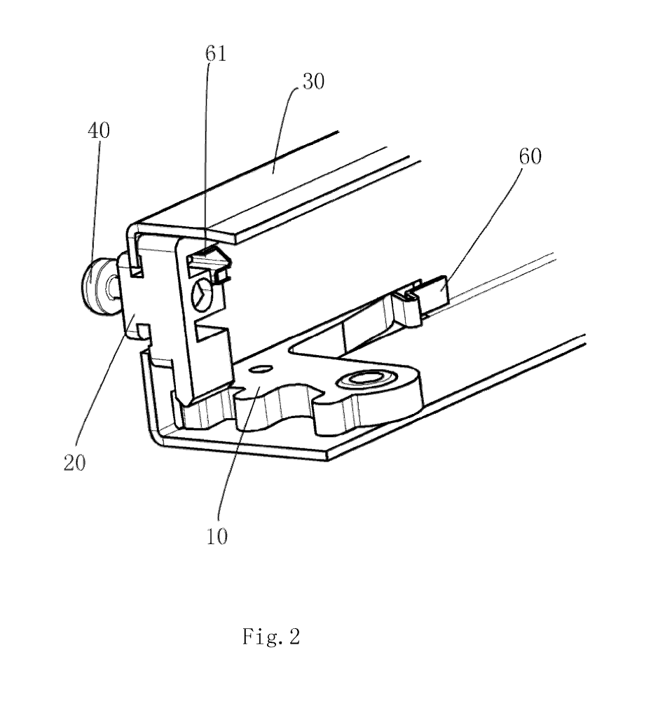

As shown in FIG. 2 and FIG. 3, the lock element 20 matches with the matching portion 31 (As shown in FIG. 1) of the plate element 30. The structures of the lock element 20 and the matching portion of the plate element 30 shown in FIGS. 1-3 are only example for clarity, and do not limit the scope of the invention. Those skilled in the art may provide various amendments to the structures.

Referring to FIG. 1, in a preferred embodiment of the present invention, a hole portion 22 is provided on the lock element 20, and the hole portion 22 is configured that the lock element 20 is fixed not to move by a screw 40 going through the hole portion 22. Those skilled in the art may provide other amendments for attaching the lock element 20 to the plate element 30 detachably.

Referring to FIG. 2, wherein the screw 40 is loosened, the lock element 20 may move freely, and the end portion of the lock element 20 is not inserted into the cut-out portion of the ejector 40, so that the ejector 10 is capable to rotate; referring to FIG. 3, wherein the screw 40 is tightened, and the end portion of the lock element 20 is inserted into the cut-out portion of the ejector 40, so that the ejector 10 does not rotate.

Referring to FIG. 1, in a preferred embodiment of the present invention, an axis hole 13 is provided on the ejector 10, and the axis hole 13 is configured that the ejector 10 is mounted on the plate element 30 by a shaft 50 going through the axis hole 13. Those skilled in the art may provide other amendments for mounting the ejector 10 on the plate element 30 rotatablely.

Referring to FIGS. 1 and 2, in a preferred embodiment of the present invention, the ejector assembly further comprises a first spring 61, wherein the first spring 61 is provided between the lock element 20 and the plate element 30, and the first spring 61 is configured to provide a force on the lock element 20 along a direction substantially perpendicular to the plan of the rotation of the ejector 10. Those skilled in the art may provide other amendments for providing a resilience force between the lock element 20 and the plate element 30.

Referring to FIGS. 1 and 2, in a preferred embodiment of the present invention, the ejector assembly further comprises a second spring 60, wherein the second spring 60 is provided between the ejector 10 and the plate element 30, and the second spring 60 is configured to provide a force on the ejector 10 along a direction of the ejector 10 rotation. Those skilled in the art may provide other amendments for providing a resilience force between the ejector 10 and the plate element 30.

Referring to FIG. 1, in a preferred embodiment of the present invention, a positioning portion 14 is provided on the ejector 10, and a positioning mated portion 32 is provided on the plate element 30, and the positioning portion 14 and the positioning mated portion 32 are configured that the positioning portion 14 is matched with the positioning mated portion 32 during the ejector 10 is mounting on the plate element 30

In a preferred embodiment of the present invention, the positioning portion is a depression or embossment, and the positioning mated portion is a embossment or depression corresponding to the positioning portion. Those skilled in the art may provide various amendments to the above structures.

Referring to FIGS. 3, in the preferred embodiment of the present invention, when the lock element 20 is fixed by the screw 40, the ejector 10 is embedded in the plate element 30.

Referring to FIGS. 2, in the preferred embodiment of the present invention, when the screw 40 is free, the ejector 10 ejects from the plate element 30 by the force.

In the preferred embodiment of the present invention, when the lock element 20 is fixed by the screw 40, the ejector 10 is embedded in the plate element 30. Therefore, when the screw 40 is tightened, it is difficult to operate the ejector by user so that a misoperation is avoided again.

The ejector assembly according to embodiments of the present invention, in one aspect, provides that the end portion of the lock element is inserted into the cut-out portion of the ejector, so that the ejector could not be rotated, and thus the misoperation is avoided and the apparatus is protected. In another aspect, when the lock element is fixed by the screw, the ejector is embedded in the plate element and thus no enough room for hand or some tools. Therefore, when the screw is tightened, it is difficult to operate the ejector by user so that a misoperation is avoided again. The above two aspects provide a protection for the apparatus. The solutions of the above aspects may be applied singly, and may be combined.

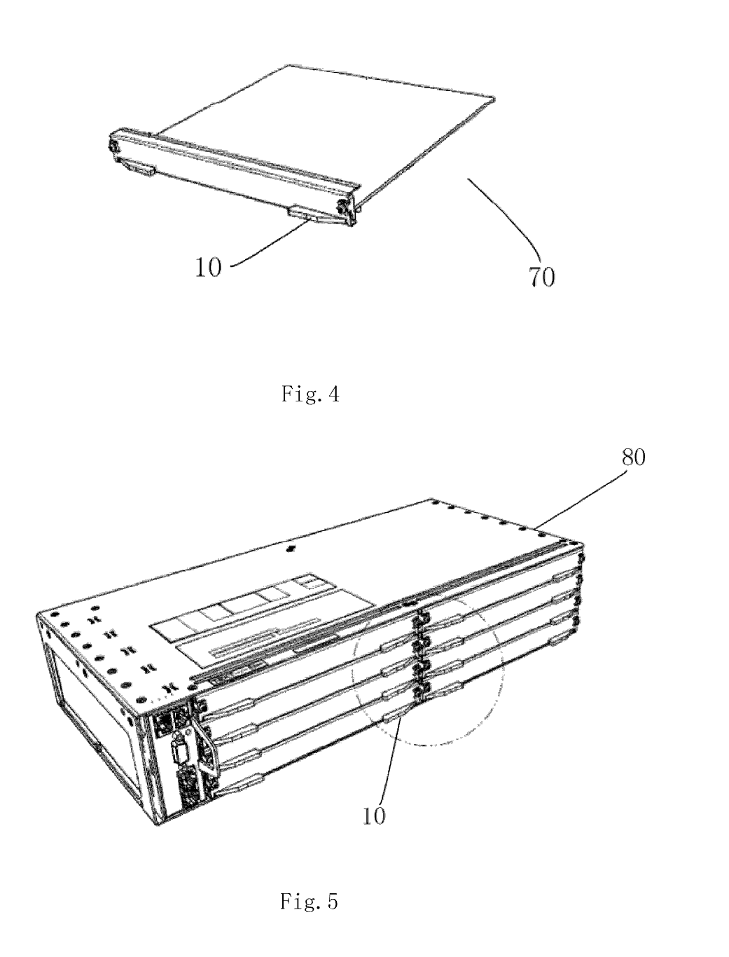

Referring to FIG. 4 and FIG. 5, as shown FIG. 4, an electronic module 70 (e.g. a line card) is equipped with the ejector assembly of the present invention; as shown FIG. 5, an electrical apparatus 80 includes one or more electronic modules 70, wherein said one or more electronic modules 70 are equipped with the ejector assembly of the present invention.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

1. An ejector assembly, comprising:
an ejector with a shape of “L”, configured to rotate around an axis; and
a lock element, configured to move along a direction substantially perpendicular to a plane of the rotation of the ejector;
wherein the ejector includes a cut-out portion, the lock element includes an end portion, and the end portion is to be provided to match with the cut-out portion to prevent the ejector from rotating.

2. The ejector assembly of claim 1, wherein the ejector assembly is provided to assemble with a plate element, a matching portion is provided on the plate element, and the lock element is provided to match with the matching portion so as to mount the lock element on the plate element.

3. The ejector assembly of claim 2, wherein a hole portion is provided on the lock element, and the hole portion is configured that the lock element is fixed by a screw going through the hole portion.

4. The ejector assembly of claim 2, wherein an axis hole is provided on the ejector, and the axis hole is configured that the ejector is mounted on the plate element by a shaft going through the axis hole.

5. The ejector assembly of claim 2, further comprising:
a first spring, wherein the first spring is provided between the lock element and the plate element, and the first spring is configured to provide a force on the lock element along a direction substantially perpendicular to the plane of the rotation of the ejector.

6. The ejector assembly of claim 2, further comprising:
a second spring, wherein the second spring is provided between the ejector the plate element, and the second spring is configured to provide a force on the ejector along a direction of the ejector rotation.

7. The ejector assembly of claim 2, wherein a positioning portion is provided on the ejector, and a positioning mated portion is provided on the plate element, and the positioning portion and the positioning mated portion are configured that the positioning portion is to be matched with the positioning mated portion when the ejector is to be mounted on the plate element.

8. The ejector assembly of claim 3, wherein when the lock element is to be fixed by the screw, the ejector is to be embedded in the plate element.

9. The ejector assembly of claim 6, wherein when the screw is free, the ejector is to be ejected from the plate element by the force.

10. An electronic module equipped with an ejector assembly, wherein the ejector assembly comprises:
an ejector with a shape of “L”, configured to rotate around an axis; and
a lock element, configured to move along a direction substantially perpendicular to a plane of the rotation of the ejector;
wherein the ejector includes a cut-out portion, the lock element includes an end portion, and the end portion is to be provided to match with the cut-out portion to prevent the ejector from rotating.

11. An electrical apparatus including one or more electronic modules, wherein said one or more electronic modules are equipped with an ejector assembly, and wherein the ejector assembly comprises:
an ejector with a shape of “L”, configured to rotate around an axis; and
a lock element, configured to move along a direction substantially perpendicular to a plane of the rotation of the ejector;
wherein the ejector includes a cut-out portion, the lock element includes an end portion, and the end portion is to be provided to match with the cut-out portion to prevent the ejector from rotating.

12. The electrical apparatus of claim 11, wherein the ejector assembly is provided to assemble with a plate element, a matching portion is provided on the plate element, and the lock element is provided to match with the matching portion so as to mount the lock element on the plate element.

13. The electrical apparatus of claim 12, wherein a hole portion is provided on the lock element, and the hole portion is configured that the lock element is fixed by a screw going through the hole portion.

14. The electrical apparatus of claim 12, wherein an axis hole is provided on the ejector, and the axis hole is configured that the ejector is mounted on the plate element by a shaft going through the axis hole.

15. The electrical apparatus of claim 12, wherein the ejector assembly further comprises a first spring, wherein the first spring is provided between the lock element and the plate element, and the first spring is configured to provide a force on the lock element along a direction substantially perpendicular to the plane of the rotation of the ejector.

16. The electrical apparatus of claim 12, wherein the ejector assembly further comprises a second spring, wherein the second spring is provided between the ejector and the plate element, and the second spring is configured to provide a force on the ejector along a direction of the ejector rotation.

17. The electrical apparatus of claim 13, wherein when the lock element is to be_fixed by the screw, the ejector is to be embedded in the plate element.

18. The electrical apparatus of claim 16, wherein when the screw is free, the ejector is to be ejected from the plate element by the force.

19. The electronic module of claim 10, wherein the ejector assembly is provided to assemble with a plate element, a matching portion is provided on the plate element, and the lock element is provided to match with the matching portion so as to mount the lock element on the plate element.

20. The electronic module of claim 19, a hole portion is provided on the lock element, and the hole portion is configured that the lock element is fixed by a screw going through the hole portion.
